(19) United States
(12) Patent Application Publication
(10) Pub. No.: US 2025/0321295 A1
(43) Pub. Date: Oct. 16, 2025

(54) DETECTION METHOD FOR USB COMMUNICATION INTERFACE DISCONNECTION AND USB CONTROL CIRCUIT

(71) Applicant: REALTEK SEMICONDUCTOR CORP., Hsinchu (TW)

(72) Inventor: Yi-Jyun Lin, Hsinchu (TW)

(73) Assignee: REALTEK SEMICONDUCTOR CORP., Hsinchu (TW)

(21) Appl. No.: 19/169,472

(22) Filed: Apr. 3, 2025

(30) Foreign Application Priority Data
Apr. 12, 2024 (TW) 113113882

(51) Int. Cl. G01R 31/69; G01R 19/165

(52) U.S. Cl. CPC G01R 31/69; G01R 19/16576

(57) ABSTRACT

A detection method for USB communication interface disconnection includes: (a) detecting a first amplitude voltage of a chirp pair signal passing through the USB communication interface and setting a value of a threshold voltage to be less than the first amplitude voltage during a speed negotiation handshake stage; (b) detecting a second amplitude voltage of a packet passing through the USB communication interface during a data transmission stage; and (c) determining that a disconnection event has occurred in response to detecting that the second amplitude voltage is greater than the threshold voltage. A USB control circuit is also provided.

### CROSS-REFERENCE TO RELATED APPLICATION

This non-provisional application claims priority under 35 U.S.C. § 119(a) to Patent Application No. 113113882 filed in Taiwan, R.O.C. on Apr. 12, 2024, the entire contents of which are hereby incorporated by reference.

### BACKGROUND

### Technical Field

The instant disclosure relates to a communication disconnection detection technology, in particular a detection method for USB communication interface disconnection and a USB control circuit.

### Related Art

When a USB device is removed from a data line, a host needs to be able to detect such disconnection event. Traditionally, the host sets a disconnection detection threshold, and a comparator compares a voltage on the data line with the disconnection detection threshold to detect the disconnection event. When the voltage on the data line is greater than the disconnection detection threshold, it indicates that the disconnection event of the USB device has occurred.

Generally, the host uses an SOF (Start of Frame) packet of the host to perform detection. When the USB device is properly connected using the USB 2.0 communication protocol, the USB device will provide an impedance of 45 ohms on the data line. The 45 ohms impedance provided by the USB device, which, combined with the 45 ohms impedance provided by the host, results in a total impedance of 22.5 ohms on the data line. When the host sends out the SOF packet, the host will output a current of 17.78 mA to the data line, resulting in a voltage of 400 mV on the data line. The USB 2.0 specification defines that the disconnection detection threshold for the USB device should be between 525 mV and 625 mV. Therefore, when the USB device is properly connected, the proper connection of the USB device will not trigger the disconnection event. However, when the USB device is removed from the data line, the SOF packet sent by the host will have a data amplitude of 800 mV due to the doubled total impedance on the data line, exceeding the disconnection detection threshold. The host thus determines that the disconnection event of the USB device has occurred.

Generally, setting the disconnection detection threshold near the upper limit is the optimized practice to avoid noise interference on the data line from falsely triggering a disconnection and causing an abnormal USB device connection. However, as ICs move into advanced manufacturing processes, the operating voltage of circuits has decreased to 0.8V or even lower. The host can no longer output enough current to raise the disconnection level to 800 mV. With process variations, the host might only be able to raise the disconnection level to around 600 mV. In such cases, the disconnection detection threshold should be set to avoid being greater than the disconnection level. It should be noted that while lowering the disconnection detection threshold can mitigate the impact of process variations, it also reduces the ability to counteract noise interference.

In practice, to improve production yield, trimming is performed on testing machines at the CP (Chip Probe) or FT (Final Test) stages to set the disconnection detection threshold for each of the ICs. However, although the optimal disconnection detection threshold for each of the ICs can be set in this way, the cost of production testing is also increased. In addition, the values after trimming need to be stored in OTP (One Time Programming Memory) or read-only memory (ROM), which will also increase the cost of the IC itself. Moreover, the values adjusted on the testing machines may not completely match the real application on the PCB.

### SUMMARY

In some embodiments, a detection method for USB communication interface disconnection comprises: (a) detecting a first amplitude voltage of a chirp pair signal passing through the USB communication interface and setting a value of a threshold voltage to be less than the first amplitude voltage during a speed negotiation handshake stage; (b) detecting a second amplitude voltage of a packet passing through the USB communication interface during a data transmission stage; and (c) determining that a disconnection event has occurred in response to detecting that the second amplitude voltage is greater than the threshold voltage.

In some embodiments, the step (a) comprises: (d) setting the threshold voltage as an initial voltage, wherein the initial voltage is the maximum value of a plurality of voltage values within a voltage range; (e) comparing the first amplitude voltage with the threshold voltage; and (f) setting the threshold voltage as the maximum value of the voltage values that are less than the threshold voltage in response to that the first amplitude voltage is greater than the threshold voltage.

In some embodiments, the detection method for USB communication interface disconnection further comprises: (g) setting the threshold voltage as the maximum value of the voltage values that are less than the threshold voltage and performing the step (e) in response to that the first amplitude voltage is not greater than the threshold voltage; and (h) repeatedly performing the step (g) until the first amplitude voltage is greater than the threshold voltage.

In some embodiments, the detection method for USB communication interface disconnection further comprises waiting for a stabilization time before performing the step (e).

In some embodiments, the step (a) comprises: (i) setting the threshold voltage as an initial voltage, wherein the initial voltage is the minimum value of a plurality of voltage values within a voltage range; (j) comparing the first amplitude voltage with the threshold voltage; and (k) setting the threshold voltage as the second highest value of the voltage values that are less than the threshold voltage in response to that the first amplitude voltage is less than the threshold voltage.

In some embodiments, the detection method for USB communication interface disconnection further comprises: (l) setting the threshold voltage as the minimum value of the voltage values that are greater than the threshold voltage and performing the step (j) in response to that the first amplitude voltage is not less than the threshold voltage; and (m) repeatedly performing the step (l) until the first amplitude voltage is less than the threshold voltage.

In some embodiments, the detection method for USB communication interface disconnection further comprises waiting for a stabilization time before performing the step (j).

In some embodiments, the detection method for USB communication interface disconnection further comprises performing the step (a) in response to detecting a chirp K signal passing through the USB communication interface.

In some embodiments, a USB control circuit comprises a USB communication interface, a voltage generation circuit and a controller. The voltage generation circuit is configured to output a threshold voltage based on a control signal. The controller is coupled to the USB communication interface and the voltage generation circuit. The controller is configured to: detect a first amplitude voltage of a chirp pair signal passing through the USB communication interface and output the control signal to set a value of the threshold voltage to be less than the first amplitude voltage during a speed negotiation handshake stage; detect a second amplitude voltage of a packet passing through the USB communication interface during a data transmission stage; and determine that a disconnection event has occurred in response to that the controller detects that the second amplitude voltage is greater than the threshold voltage.

In some embodiments, the controller comprises a comparator and a control unit. The comparator is configured to compare the first amplitude voltage with the threshold voltage to output a comparison result signal. The control unit is coupled to the comparator. The control unit is configured to: output the control signal to the voltage generation circuit to set the threshold voltage as an initial voltage, wherein the initial voltage is the maximum value of a plurality of voltage values within a voltage range; determine whether the first amplitude voltage is greater than the threshold voltage based on the comparison result signal, and output the control signal to set the threshold voltage as the maximum value of the voltage values that are less than the threshold voltage in response to that the control unit determines that the first amplitude voltage is greater than the threshold voltage based on the comparison result signal; and determine that the disconnection event has occurred in response to that the controller detects that the second amplitude voltage is greater than the threshold voltage.

In some embodiments, in response to that the control unit determines that the first amplitude voltage is not greater than the threshold voltage based on the comparison result signal, the control unit outputs the control signal to set the threshold voltage as the maximum value of the voltage values that are less than the threshold voltage, and then again the control unit determines whether the first amplitude voltage is greater than the threshold voltage based on the comparison result signal.

In some embodiments, the comparator further waits for a stabilization time before comparing the first amplitude voltage with the threshold voltage to output the comparison result signal.

In some embodiments, the controller comprises a comparator and a control unit. The comparator is configured to compare the first amplitude voltage with the threshold voltage to output a comparison result signal. The control unit is coupled to the comparator. The control unit is configured to: output the control signal to the voltage generation circuit to set the threshold voltage as an initial voltage, wherein the initial voltage is the minimum value of a plurality of voltage values within a voltage range; determine whether the first amplitude voltage is less than the threshold voltage based on the comparison result signal, and output the control signal to set the threshold voltage as the second highest value of the voltage values that are less than the threshold voltage in response to that the control unit determines that the first amplitude voltage is less than the threshold voltage based on the comparison result signal; and determine that the disconnection event has occurred in response to that the controller detects that the second amplitude voltage is greater than the threshold voltage.

In some embodiments, in response to that the control unit determines that the first amplitude voltage is not less than the threshold voltage based on the comparison result signal, the control unit outputs the control signal to set the threshold voltage as the minimum value of the voltage values that are greater than the threshold voltage, and then again the control unit determines whether the first amplitude voltage is less than the threshold voltage based on the comparison result signal.

In some embodiments, the controller is further configured to, in response to that the controller detects a chirp K signal passing through the USB communication interface, detect the first amplitude voltage of the chirp pair signal passing through the USB communication interface during the speed negotiation handshake stage, and output the control signal to set the voltage value of the threshold voltage to be less than the first amplitude voltage.

In some embodiments, the controller further comprises a register. The register is coupled to the voltage generation circuit. The register is configured to store a set value. The control signal output by the controller corresponds to the set value.

To sum up, in any embodiment of the USB control circuit, the threshold voltage is set during the speed negotiation handshake stage. During the data transmission stage, the value of the threshold voltage is already set. Therefore, there is no need for trimming on the testing machines during the CP or FT stages to set the threshold voltage for each of the ICs, thus greatly reducing testing costs.

The following will describe the detailed features and advantages of the instant disclosure in detail in the detailed description. The content of the description is sufficient for any person skilled in the art to comprehend the technical context of the instant disclosure and to implement it accordingly. According to the content, claims and drawings disclosed in the instant specification, any person skilled in the art can readily understand the goals and advantages of the instant disclosure.

### BRIEF DESCRIPTION OF THE DRAWINGS

The disclosure will become more fully understood from the detailed description given herein below for illustration only, and thus not limitative of the disclosure, wherein:

FIG. 1 illustrates a block diagram of an embodiment of a USB control circuit and a USB device;

FIG. 2 illustrates a flowchart of an embodiment of a detection method for USB communication interface disconnection;

FIG. 3 illustrates a block diagram of an embodiment of a controller;

FIG. 4 illustrates a flowchart of the first embodiment of a step S01;

FIG. 5 illustrates a flowchart of the second embodiment of the step S01;

FIG. 6 illustrates a diagram of an embodiment of an initial handshake stage, a speed negotiation handshake stage, a second handshake stage, and a data transmission stage;

FIG. 7 illustrates a diagram of the embodiment of the data transmission stage; and

FIG. 8 illustrates a diagram of an embodiment of a comparator.

### DETAILED DESCRIPTION

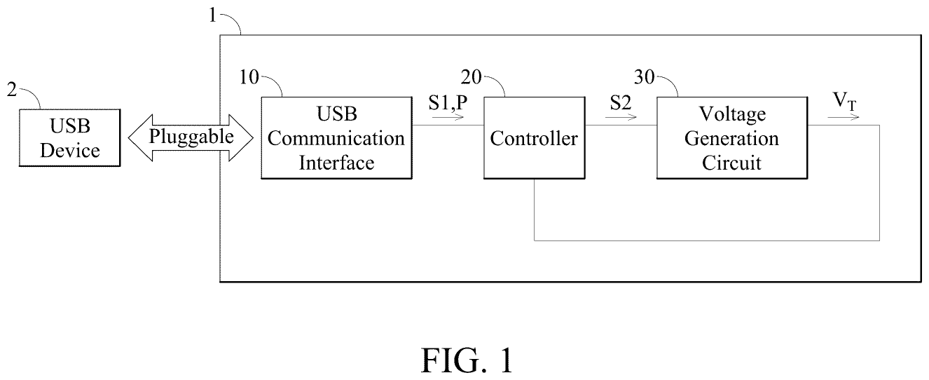

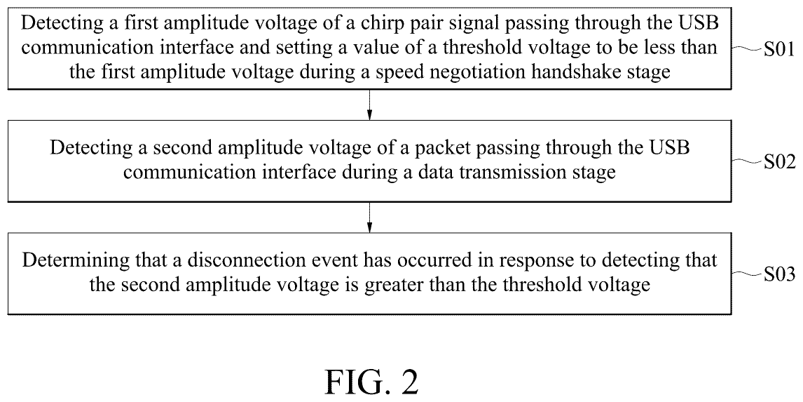

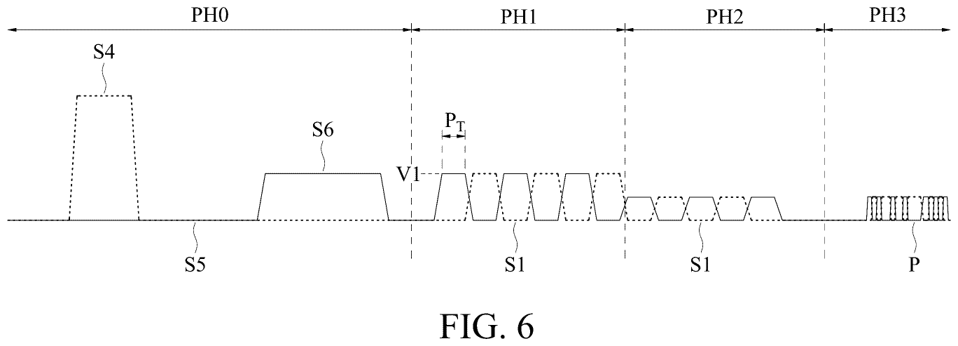

Please refer to FIG. 1, FIG. 2, and FIG. 6. A USB control circuit 1 comprises a USB communication interface 10, a voltage generation circuit 30, and a controller 20. A USB device 2 establishes or interrupts an electrical connection with the USB communication interface 10 through plugging and unplugging. The controller 20 is coupled to the USB communication interface 10 and the voltage generation circuit 30. In some embodiments, the USB control circuit 1 is the circuit of a host. In some embodiments, the USB device 2 is a USB 2.0 device, but the instant disclosure is not limited thereto. In some embodiments, the USB device 2 may also be a USB 3.0 device, a USB 3.1 device, a USB 3.2 device, a USB 4.0 device, or any device that supports the USB 2.0 communication protocol.

The voltage generation circuit 30 is configured to output a threshold voltage V_{T} based on a control signal S2. The controller 20 is configured to, during a speed negotiation handshake stage PH1, detect a first amplitude voltage V1 of a chirp pair signal S1 passing through the USB communication interface 10 and output the control signal S2 to set a value of the threshold voltage V_{T} to be less than the first amplitude voltage V1 (step S01). Additionally, the controller 20 detects a second amplitude voltage V2 of a packet P passing through the USB communication interface 10 during a data transmission stage PH3 (step S02), and the controller 20 determines that a disconnection event has occurred in response to that the controller 20 detects that the second amplitude voltage V2 is greater than the threshold voltage V_{T} (step S03). In this way, the self-adaptive optimization setting of the threshold voltage V_{T} can be achieved during the speed negotiation handshake stage PH1, and the threshold voltage V_{T} does not need to be tested in advance before the product comprising the USB control circuit 1 is shipped.

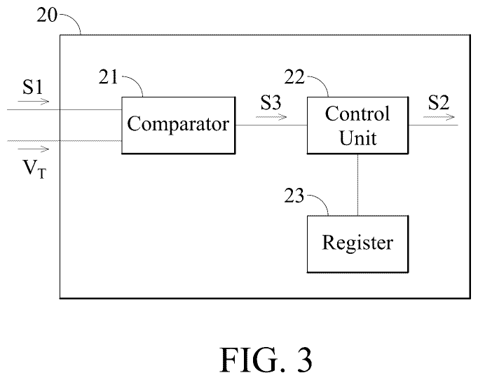

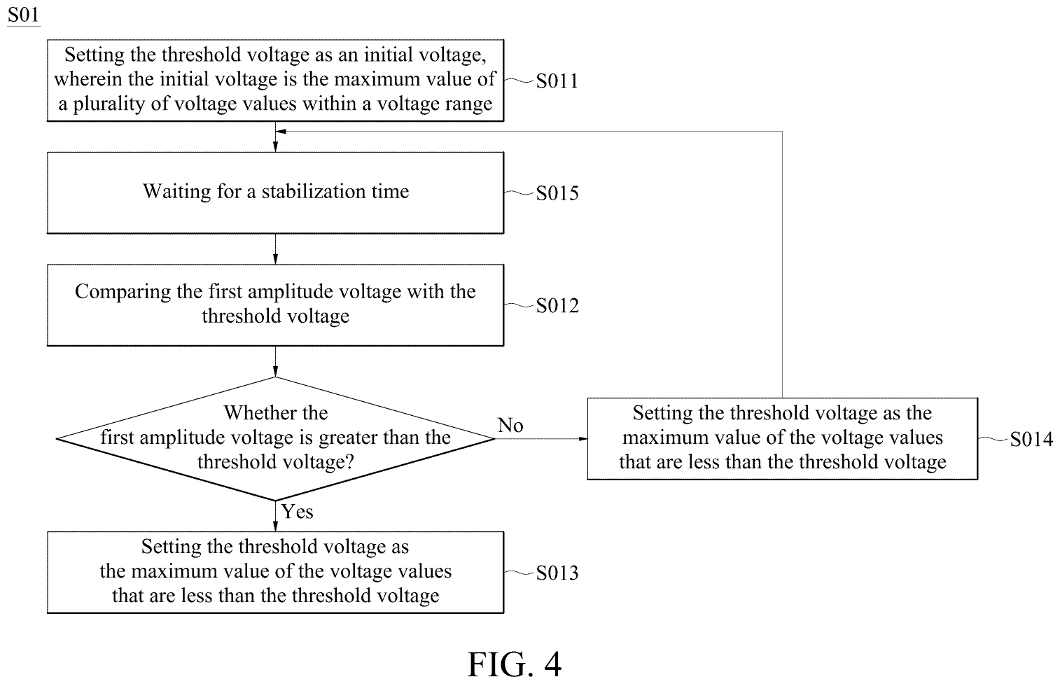

Please refer to FIG. 3 and FIG. 4. In some embodiments, the controller 20 comprises a comparator 21 and a control unit 22. The control unit 22 is coupled to the comparator 21. The comparator 21 is configured to compare the first amplitude voltage V1 with the threshold voltage V_{T} to output a comparison result signal S3. The control unit 22 is configured to output the control signal S2 to the voltage generation circuit 30 to set the threshold voltage V_{T} as an initial voltage and set the value of the threshold voltage V_{T} based on the comparison result signal S3. The following further illustrates the way to set the threshold voltage V_{T} in the aforementioned step S01.

The first embodiment of the step S01 is illustrated here. In some embodiments, the control unit 22 sets the threshold voltage V_{T} as the initial voltage, which is the maximum value of a plurality of voltage values within a voltage range (step S011), and the control unit 22 determines whether the first amplitude voltage V1 is greater than the threshold voltage V_{T} based on the comparison result signal S3 (step S012). The control unit 22 outputs the control signal S2 to set the threshold voltage V_{T} as the maximum value of the voltage values that are less than the threshold voltage V_{T} in response to that the control unit 22 determines that the first amplitude voltage V1 is greater than the threshold voltage V_{T} based on the comparison result signal S3 (step S013), and then the control unit 22 ends the step S01. In response to that the control unit 22 determines that the first amplitude voltage V1 is not greater than the threshold voltage V_{T} based on the comparison result signal S3, the control unit 22 outputs the control signal S2 to set the threshold voltage V_{T} as the maximum value of the voltage values that are less than the threshold voltage V_{T} (step S014), and then again the control unit 22 determines whether the first amplitude voltage V1 is greater than the threshold voltage V_{T} based on the comparison result signal S3 (step S012). In other words, in some embodiments, in response to that the control unit 22 determines that the first amplitude voltage V1 is not greater than the threshold voltage V_{T} based on the comparison result signal S3, the control unit 22 will repeat the step S014 and the step SO12 until the first amplitude voltage V1 is greater than the threshold voltage V_{T}.

For example, assuming that the voltage range is between 525 mV and 640 mV, the number of the voltage values within the voltage range is 8, and the voltage values are, in ascending order, 530 mV, 545 mV, 560 mV, 575 mV, 590 mV, 605 mV, 620 mV, and 635 mV, because the maximum value of the voltage values within the voltage range at this time is 635 mV, the control unit 22 outputs the control signal S2 to the voltage generation circuit 30 to set the threshold voltage V_{T} as 635 mV. The comparator 21 compares the first amplitude voltage V1 with 635 mV and outputs the comparison result signal S3. In response to that the control unit 22 determines, based on the comparison result signal S3, that the first amplitude voltage V1 is greater than 635 mV, the control unit 22 outputs the control signal S2 to set the threshold voltage V_{T} as the maximum value of the voltage values that are less than 635 mV, which is 620 mV.

In response to that the control unit 22 determines that the first amplitude voltage V1 is not greater than 635 mV based on the comparison result signal S3, the control unit 22 outputs the control signal S2 to set the threshold voltage V_{T} as the maximum value of the voltage values that are less than 635 mV, which is 620 mV, and then again the control unit 22 determines whether the first amplitude voltage V1 is greater than 620 mV based on the comparison result signal S3. Assuming that the first amplitude voltage V1 at this time is 600 mV, the control unit 22 will repeatedly perform the step S014 and the step S012 until the first amplitude voltage V1 (i.e., 600 mV) is greater than the threshold voltage V_{T} (590 mV, which is the maximum value of the voltage values less than 600 mV within the voltage range). In response to that the control unit 22 determines, based on the comparison result signal S3, that the first amplitude voltage V1 (i.e., 600 mV) is greater than the threshold voltage V_{T} (i.e., 590 mV), the control unit 22 outputs the control signal S2 to set the threshold voltage V_{T} as the maximum value of the voltage values that are less than 590 mV (i.e., 575 mV).

In the step S013, in response to that the control unit 22 determines, based on the comparison result signal S3, that the first amplitude voltage V1 is greater than the threshold voltage V_{T}, the control unit 22 outputs the control signal S2 with a value less than the threshold voltage V_{T}, instead of directly outputting the control signal S2 with the current value of the threshold voltage V_{T}. The reason for not directly outputting the control signal S2 with the current value of the threshold voltage V_{T} is to maintain a margin to avoid the threshold voltage V_{T} from being too close to the first amplitude voltage V1, which could cause the result of detection in the step S03 to be inaccurate. The reason why the control unit 22 chooses to output the control signal S2 with the maximum value of the voltage values that are less than the threshold voltage V_{T} is to avoid excessively lowering the threshold voltage V_{T}, which would also greatly reduces the ability to counteract noise for the USB control circuit 1. Through the aforementioned first embodiment of the step S01, an appropriate value for the threshold voltage V_{T} can be determined.

In some embodiments, the voltage range is set according to the disconnection detecting threshold defined by the USB 2.0 specification, but the instant disclosure is not limited thereto. The voltage range can also be set according to the disconnection detecting thresholds defined by the USB 3.0, USB 3.1, USB 3.2, or USB 4.0 specifications. In the aforementioned embodiment, the number of the voltage values within the voltage range is 8, but the instant disclosure is not limited thereto. In some embodiments, the number of the voltage values within the voltage range may be a power of 2, such as 2, 4, 8, 16, 32, etc.

In some embodiments, before the comparator 21 compares the first amplitude voltage V1 with the threshold voltage V_{T} to output the comparison result signal S3, the comparator 21 further waits for a stabilization time (step S015) to prevent the first amplitude voltage V1 and the threshold voltage V_{T} from becoming metastable due to changes. In some embodiments, the stabilization time may be but not limited to 1 microsecond (μs).

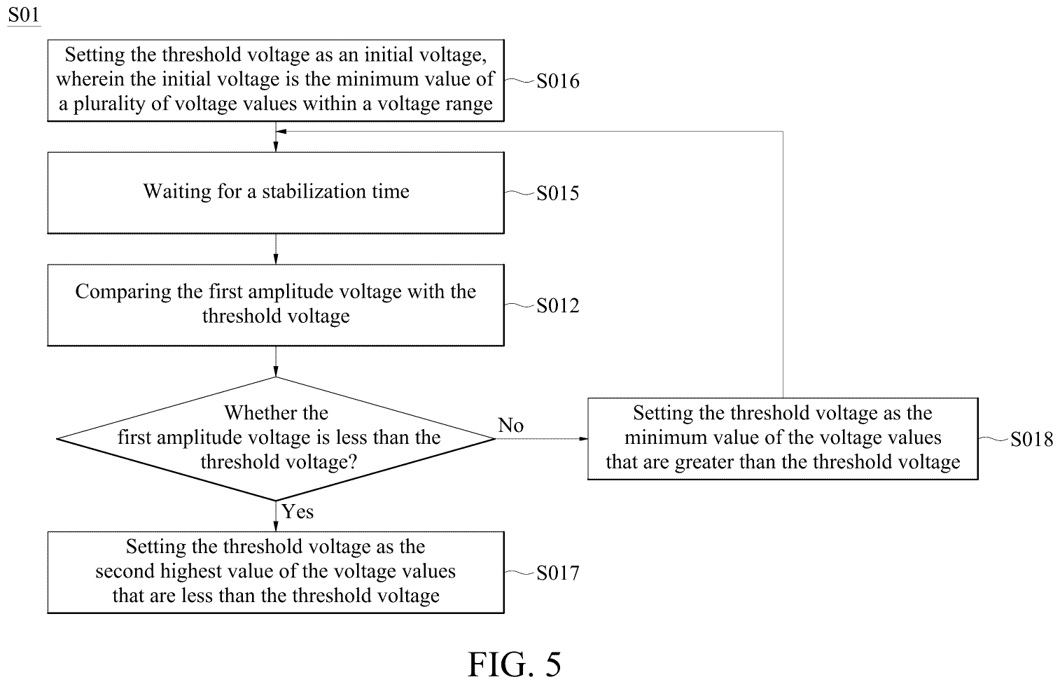

Please refer to FIG. 5. The second embodiment of the step S01 is illustrated here. In some embodiments, the control unit 22 sets the threshold voltage V_{T} as the initial voltage, which is the minimum value of a plurality of voltage values within a voltage range (step S016), and the control unit 22 determines whether the first amplitude voltage V1 is less than the threshold voltage V_{T} based on the comparison result signal S3 (step S012). The control unit 22 outputs the control signal S2 to set the threshold voltage V_{T} as the second highest value of the voltage values that are less than the threshold voltage V_{T} in response to that the control unit 22 determines that the first amplitude voltage V1 is less than the threshold voltage V_{T} based on the comparison result signal S3 (step S017), and then the control unit 22 ends the step S01. In response to that the control unit 22 determines that the first amplitude voltage V1 is not less than the threshold voltage V_{T} based on the comparison result signal S3, the control unit 22 outputs the control signal S2 to set the threshold voltage V_{T} as the minimum value of the voltage values that are greater than the threshold voltage V_{T} (step S018), and then again the control unit 22 determines whether the first amplitude voltage V1 is less than the threshold voltage V_{T} based on the comparison result signal S3 (step S012). In other words, in some embodiments, in response to that the control unit 22 determines that the first amplitude voltage V1 is not less than the threshold voltage V_{T} based on the comparison result signal S3, the control unit 22 will repeat the step S018 and the step S012 until the first amplitude voltage V1 is less than the threshold voltage V_{T}.

For example, assuming that the voltage range is between 525 mV and 640 mV, the number of the voltage values within the voltage range is 8, the voltage values are, in ascending order, 530 mV, 545 mV, 560 mV, 575 mV, 590 mV, 605 mV, 620 mV, and 635 mV, and the first amplitude voltage V1 at this time is 600 mV, because the minimum value of the voltage values within the voltage range is 530 mV, the control unit 22 outputs the control signal S2 to the voltage generation circuit 30 to set the threshold voltage V_{T} as 530 mV. The comparator 21 compares the first amplitude voltage V1 (i.e., 600 mV) with 530 mV and outputs the comparison result signal S3. In response to that the control unit 22 determines, based on the comparison result signal S3, that the first amplitude voltage V1 (i.e., 600 mV) is not less than 530 mV, the control unit 22 outputs the control signal S2 to set the threshold voltage V_{T} as the minimum value of the voltage values that are greater than 530 mV (i.e., 545 mV), and then again the control unit 22 determines whether the first amplitude voltage V1 is less than 545 mV based on the comparison result signal S3. The control unit 22 will repeatedly perform the step S018 and the step S012 until the first amplitude voltage V1 (i.e., 600 mV) is less than the threshold voltage V_{T} (605 mV, which is the minimum value of the voltage values greater than 600 mV within the voltage range). In response to that the control unit 22 determines, based on the comparison result signal S3, that the first amplitude voltage V1 (i.e., 600 mV) is less than the threshold voltage V_{T} (i.e., 605 mV), the control unit 22 outputs the control signal S2 to set the threshold voltage V_{T} as the second highest value of the voltage values that are less than 605 mV (i.e., 575 mV). Through the aforementioned second embodiment of the step S01, the appropriate value for the threshold voltage V_{T} can be determined.

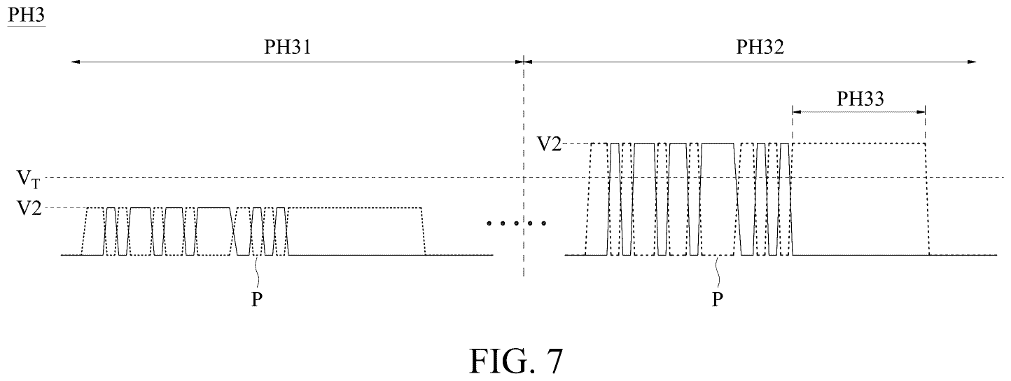

Please refer to FIG. 6 and FIG. 7. An initial handshake stage PH0, the speed negotiation handshake stage PH1, a second handshake stage PH2, and the data transmission stage PH3 shown in FIG. 6 all occur after the USB device 2 establishes an electrical connection with the USB communication interface 10 through plugging the USB device 2 into the USB communication interface 10. During the speed negotiation handshake stage PH1, the second handshake stage PH2, and the data transmission stage PH3, the host provides a host-end resistor on a data line. During each of the second handshake stage PH2 and a first data transmission stage PH31 of the data transmission stage PH3, the USB device 2 provides a device-end resistor on the data line.

During the initial handshake stage PH0, firstly, the USB device 2 provides an initial signal S4 on the data line. In some embodiments, the voltage of the initial signal S4 may be but not limited to 3 volts (V). After the USB device 2 provides the initial signal S4 on the data line, the host provides a reset signal S5 on the data line. Then, the USB device 2 provides a chirp K signal S6 on the data line. In some embodiments, the controller 20 is further configured to perform the step S01 in response to the chirp K signal S6. In other words, in some embodiments, after the USB device 2 provides the chirp K signal S6 on the data line, the USB control circuit 1 enters into the speed negotiation handshake stage PH1.

During the speed negotiation handshake stage PH1, the USB device 2 has not yet provided the device-end resistor on the data line, and such scenario corresponds to the disconnection scenario that occurs after the USB device 2 is removed from the data line. Therefore, the speed negotiation handshake stage PH1 is suitable for determining the appropriate value for the threshold voltage V_{T} configured to determine the disconnection scenario (as in the processes of the aforementioned embodiments shown in FIG. 4 and FIG. 5). Specifically, in some embodiments, the controller 20 detects the first amplitude voltage V1 of the chirp pair signal S1 during the speed negotiation handshake stage PH1 to find and set the voltage value of the threshold voltage V_{T} as the appropriate value less than the first amplitude voltage V1 (step S01). In some embodiments, the chirp pair signal S1 is provided by the host as a chirp KJ pair signal, and each of the packets of the chirp pair signal S1 has a minimum duration P_{T} of at least 40 μs. In some embodiments, each of the packets of the chirp pair signal S1 has a duration P_{T} ranging from 40 μs to 60 μs.

During the second handshake stage PH2, the USB device 2 begins to provide the device-end resistor on the data line. The device-end resistor is connected in parallel with the host-end resistor provided by the host, thereby reducing the overall impedance on the data line, which in turn lowers the voltage of the chirp pair signal S1 at this time. In some embodiments, the resistance values of the device-end resistor and the host-end resistor are the same, but the instant disclosure is not limited thereto. In some embodiments, both the device-end resistor and the host-end resistor are 45 ohms (Ω), that is, in some embodiments, the overall impedance on the data line during the second handshake stage PH2 is 22.5 Ω, but the instant disclosure is not limited thereto.

During the data transmission stage PH3, the controller 20 detects the second amplitude voltage V2 of the packet P on the data line (step S02) and determines that the disconnection event has occurred in response to that the controller 20 detects that the second amplitude voltage V2 is greater than the threshold voltage V_{T} (step S03).

Please refer to FIG. 7. The data transmission stage PH3 comprises the first data transmission stage PH31 and a second data transmission stage PH32. During the first data transmission stage PH31, since the USB device 2 has not yet been removed from the data line, the second amplitude voltage V2 is less than the threshold voltage V_{T}, and the controller 20 does not detect the disconnection event.

During the second data transmission stage PH32, the USB device 2 is removed from the data line. Due to the removal of the device-end resistor provided by the USB device 2, the overall impedance on the data line increases, causing the second amplitude voltage V2 to also increase to a value greater than the threshold voltage V_{T}. Therefore, the controller 20 determines that the disconnection event has occurred.

In some embodiments, the packet P may be but not limited to an SOF (Start of Frame) packet provided by the host on the data line. In some embodiments, the frequency of the packet P is greater than the frequency of the chirp pair signal S1. In some embodiments, the packet P is a high-speed signal with a frequency of 480 MHz, but the instant disclosure is not limited thereto.

In some embodiments, the controller 20 detects the second amplitude voltage V2 of the packet P on the data line and determines that the disconnection event has occurred in response to that the second amplitude voltage V2 is greater than the threshold voltage V_{T} through the control unit 22. In some embodiments, the control unit 22 detects the second amplitude voltage V2 of the packet P on the data line and determines that the disconnection event has occurred in response to that the second amplitude voltage V2 is greater than the threshold voltage VT during the detection stage PH33, but the instant disclosure is not limited thereto. In some embodiments, the duration of the detection stage PH33 may be but not limited to 80 nanoseconds (ns).

Please refer to FIG. 3. In some embodiments, the controller 20 further comprises a register 23. The register 23 is coupled to the control unit 22. The register 23 is configured to store a set value. The control signal S2 output by the controller 20 corresponds to the set value. In some embodiments, the voltage generation circuit 30 is provided in the controller 20.

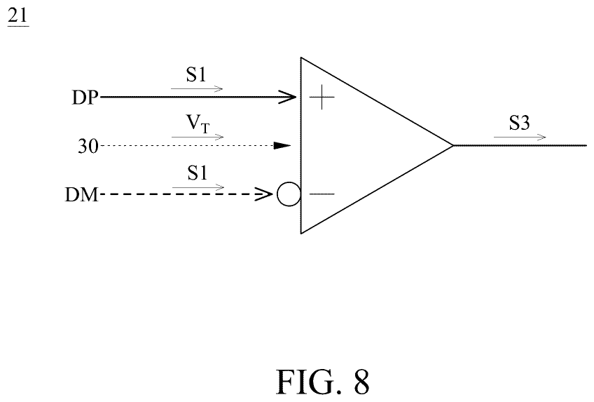

Please refer to FIG. 8. In some embodiments, the comparator 21 may be but not limited to an operational amplifier. In some embodiments, since the data line comprises a data positive line DP and a data minus line DM, the comparator 21 uses the chirp pair signal S1 which is received from the data positive line DP and the data minus line DM and the threshold voltage V_{T} which is received from the voltage generation circuit 30 as inputs to compare the first amplitude voltage V1 with the threshold voltage V_{T}, thereby outputting the comparison result signal S3.

To sum up, in any embodiment of the USB control circuit 1, the threshold voltage V_{T} is set during the speed negotiation handshake stage PH1. During the data transmission stage PH3, the value of the threshold voltage V_{T} is already set. Therefore, there is no need for trimming on the testing machines during the CP or FT stages to set the threshold voltage V_{T} for each of the ICs, thus greatly reducing testing costs.

Although the instant disclosure has been described in considerable detail with reference to certain preferred embodiments thereof, the disclosure is not for limiting the scope of the invention. Persons having ordinary skill in the art may make various modifications and changes without departing from the scope and spirit of the invention. Therefore, the scope of the appended claims should not be limited to the description of the preferred embodiments described above.

What is claimed is:

1. A detection method for USB communication interface disconnection, comprising:
(a) detecting a first amplitude voltage of a chirp pair signal passing through the USB communication interface and setting a value of a threshold voltage to be less than the first amplitude voltage during a speed negotiation handshake stage;
(b) detecting a second amplitude voltage of a packet passing through the USB communication interface during a data transmission stage; and
(c) determining that a disconnection event has occurred in response to detecting that the second amplitude voltage is greater than the threshold voltage.

2. The detection method for USB communication interface disconnection according to claim 1, wherein the step (a) comprises:
(d) setting the threshold voltage as an initial voltage, wherein the initial voltage is the maximum value of a plurality of voltage values within a voltage range;
(e) comparing the first amplitude voltage with the threshold voltage; and
(f) setting the threshold voltage as the maximum value of the voltage values that are less than the threshold voltage in response to that the first amplitude voltage is greater than the threshold voltage.

3. The detection method for USB communication interface disconnection according to claim 2, further comprising:
(g) setting the threshold voltage as the maximum value of the voltage values that are less than the threshold voltage and performing the step (e) in response to that the first amplitude voltage is not greater than the threshold voltage; and
(h) repeatedly performing the step (g) until the first amplitude voltage is greater than the threshold voltage.

4. The detection method for USB communication interface disconnection according to claim 3, further comprising:
waiting for a stabilization time before performing the step (e).

5. The detection method for USB communication interface disconnection according to claim 1, wherein the step (a) comprises:
(i) setting the threshold voltage as an initial voltage, wherein the initial voltage is the minimum value of a plurality of voltage values within a voltage range;
(j) comparing the first amplitude voltage with the threshold voltage; and
(k) setting the threshold voltage as the second highest value of the voltage values that are less than the threshold voltage in response to that the first amplitude voltage is less than the threshold voltage.

6. The detection method for USB communication interface disconnection according to claim 5, further comprising:
(l) setting the threshold voltage as the minimum value of the voltage values that are greater than the threshold voltage and performing the step (j) in response to that the first amplitude voltage is not less than the threshold voltage; and
(m) repeatedly performing the step (1) until the first amplitude voltage is less than the threshold voltage.

7. The detection method for USB communication interface disconnection according to claim 6, further comprising:
waiting for a stabilization time before performing the step (j).

8. The detection method for USB communication interface disconnection according to claim 1, further comprising:
performing the step (a) in response to detecting a chirp K signal passing through the USB communication interface.

9. A USB control circuit, comprising:
a USB communication interface;
a voltage generation circuit configured to output a threshold voltage based on a control signal; and
a controller coupled to the USB communication interface and the voltage generation circuit, wherein the controller is configured to:
detect a first amplitude voltage of a chirp pair signal passing through the USB communication interface and output the control signal to set a value of the threshold voltage to be less than the first amplitude voltage during a speed negotiation handshake stage;
detect a second amplitude voltage of a packet passing through the USB communication interface during a data transmission stage; and
determine that a disconnection event has occurred in response to that the controller detects that the second amplitude voltage is greater than the threshold voltage.

10. The USB control circuit according to claim 9, wherein the controller comprises:
a comparator configured to compare the first amplitude voltage with the threshold voltage to output a comparison result signal; and
a control unit coupled to the comparator, wherein the control unit is configured to:
output the control signal to the voltage generation circuit to set the threshold voltage as an initial voltage, wherein the initial voltage is the maximum value of a plurality of voltage values within a voltage range;
determine whether the first amplitude voltage is greater than the threshold voltage based on the comparison result signal, and output the control signal to set the threshold voltage as the maximum value of the voltage values that are less than the threshold voltage in response to that the control unit determines that the first amplitude voltage is greater than the threshold voltage based on the comparison result signal; and
determine that the disconnection event has occurred in response to that the controller detects that the second amplitude voltage is greater than the threshold voltage.

11. The USB control circuit according to claim 10, wherein in response to that the control unit determines that the first amplitude voltage is not greater than the threshold voltage based on the comparison result signal, the control unit outputs the control signal to set the threshold voltage as the maximum value of the voltage values that are less than the threshold voltage, and then again the control unit determines whether the first amplitude voltage is greater than the threshold voltage based on the comparison result signal.

12. The USB control circuit according to claim 11, wherein the comparator further waits for a stabilization time before comparing the first amplitude voltage with the threshold voltage to output the comparison result signal.

13. The USB control circuit according to claim 9, wherein the controller comprises:
a comparator configured to compare the first amplitude voltage with the threshold voltage to output a comparison result signal; and
a control unit coupled to the comparator, wherein the control unit is configured to:
output the control signal to the voltage generation circuit to set the threshold voltage as an initial voltage, wherein the initial voltage is the minimum value of a plurality of voltage values within a voltage range;
determine whether the first amplitude voltage is less than the threshold voltage based on the comparison result signal, and output the control signal to set the threshold voltage as the second highest value of the voltage values that are less than the threshold voltage in response to that the control unit determines that the first amplitude voltage is less than the threshold voltage based on the comparison result signal; and
determine that the disconnection event has occurred in response to that the controller detects that the second amplitude voltage is greater than the threshold voltage.

14. The USB control circuit according to claim 13, wherein in response to that the control unit determines that the first amplitude voltage is not less than the threshold voltage based on the comparison result signal, the control unit outputs the control signal to set the threshold voltage as the minimum value of the voltage values that are greater than the threshold voltage, and then again the control unit determines whether the first amplitude voltage is less than the threshold voltage based on the comparison result signal.

15. The USB control circuit according to claim 14, wherein the comparator further waits for a stabilization time before comparing the first amplitude voltage with the threshold voltage to output the comparison result signal.

16. The USB control circuit according to claim 9, wherein the controller is further configured to, in response to that the controller detects a chirp K signal passing through the USB communication interface, detect the first amplitude voltage of the chirp pair signal passing through the USB communication interface during the speed negotiation handshake stage, and output the control signal to set the voltage value of the threshold voltage to be less than the first amplitude voltage.

17. The USB control circuit according to claim 9, wherein the controller further comprises:
a register coupled to the control unit, wherein the register is configured to store a set value, and the control signal output by the controller corresponds to the set value.
